(19) United States
(12) Patent Application Publication
(10) Pub. No.: US 2002/0105001 A1
(43) Pub. Date: Aug. 8, 2002

(54) Optical to electrical interconnect structure

(76) Inventor: Thomas Francis Strelchun, Mertztown, PA (US)

Correspondence Address: JONES VOLENTINE, L.L.C., Suite 150, 12200 Sunrise Valley Drive, Reston, VA, 20191, US

(21) Appl. No.: 09/777,869

(22) Filed: Feb. 7, 2001

(51) Int. Cl. H01L 27/15

(52) U.S. Cl. 257/81

(57) ABSTRACT

A structure for connecting an optical device to an electrical device includes an assembly. At least one electrical connection connects the assembly to at least one transmission line. The distance (or length) of the electrical connection is less than approximately one-fourth of a wavelength of a signal traversing the electrical connection. The present invention fosters also impedance matching between the optical device and the transmission lines.

### FIELD OF THE INVENTION

The present invention relates generally to an optical-to-electrical interconnect, and particularly to a structure for coupling an optical device to an electrical device.

### BACKGROUND OF THE INVENTION

The increasing demand for high-speed voice and data communications has led to an increased reliance on optical communications, particularly optical fiber communications. The use of optical signals as a vehicle to carry information at high speeds is preferred in many instances to carrying information at other electromagnetic wavelengths/frequencies in media such as microwave transmission lines, coaxial cable lines and twisted-pair transmission lines. Advantages of optical media are, among others, higher bandwidth, greater immunity to electromagnetic interference, and lower propagation loss. In fact, it is common for high-speed optical communications systems to have signal rates in the range of approximately several gigabits per second (Gbit/sec) to approximately several tens of Gbit/sec, and higher. However, while the optical communication system is useful for the transmission of information, ultimately the optical signals may have to be converted to electrical signals (and vice-versa). As such, an electrical interface is required between the optical device(s) and the electrical device(s).

One commonly used structure in optical communications is the discrete package device. Often, the discrete package device includes a discrete optoelectronic component, which is connected to an electrical lead frame. The entire optical component and lead frame are then encapsulated in a suitable material (e.g. a resin molding) or are disposed in a ceramic housing. While the discrete package optoelectronic device has benefits including hermeticity of design and a relative ease of testing, there are drawbacks to such a structure.

One such drawback to the conventional discrete package optoelectronic device is its overall size or volume. Particularly, the volume required for the active device and any necessary optics in an integrated package is often too great for many applications in which integration and miniaturization is mandated.

Another drawback to the discrete package optoelectronic device is its high performance limitations. The discrete package optoelectronic device generally requires external leads and connections to effect the connection to electrical devices, as mentioned above. These leads are often relatively long and can significantly impair high frequency performance. To this end, in present day optical communication systems, 10 Gbit per second (and higher) transmission speeds are becoming desirable. The relatively longleads required of conventional discrete package optoelectronic devices may contribute to a parasitic inductance, which can significantly impact the speed of the signal which can be transmitted to and from the optoelectronic device. As such, conventional discrete package optoelectronic devices generally have an upper-end transmission/reception speed of 10 Gbit per second due to the parasitic inductance of the relatively long leads of the package.

Finally, another potential problem posed by the discrete package optoelectronic devices described above is difficult impedance matching. As is well known to one of ordinary skill in the art, impedance matching is necessary to assure good performance and to assure signal quality. For example, if the devices and transmission lines are not impedance-matched, undesirable back-reflections may result, and these back reflections may significantly interfere with the effective transmission of signals. To be specific, reflections due to impedance mismatch may result in interference of the signal carried to and from the device causing attenuation and/or distortion of the signal, and, ultimately transmission error. The problems associated with impedance matching are pronounced in high frequency applications.

Accordingly, what is needed is a packaging scheme which fosters a high-performance optical-to-electrical interface by overcoming the shortfalls of the conventional art described above.

### SUMMARY OF THE INVENTION

According to an exemplary embodiment of the present invention, a structure for connecting an optical device to an electrical device is disclosed. An assembly is connected to least one transmission line by at least one electrical connection. The at least one electrical connection, which connects the assembly to the at least one transmission line has a length of less than one-fourth of a wavelength of a signal traversing the at least one electrical connection.

### BRIEF DESCRIPTION OF THE DRAWINGS

The invention is best understood from the following detailed description when read with the accompanying drawing figures. It is emphasized that the various features are not necessarily drawn to scale. In fact, the dimensions may be arbitrarily increased or decreased for clarity of discussion.

FIG. 1 is a cross-sectional view along line 1-1 of FIG. 2 showing an optical-to-electrical interconnect structure according to an exemplary embodiment of the present invention.

FIG. 2 is a top view of an optical-to-electrical interconnect structure according to an exemplary embodiment of the present invention.

FIG. 3 is a front view of an optical-to-electrical interconnect structure according to an exemplary embodiment of the present invention.

FIG. 4 is a cross-sectional view of an optical assembly according to an exemplary embodiment of the present invention.

FIG. 5 is a cross-sectional view of an exemplary embodiment of the present invention incorporating a thermoelectric cooler (TEC) according to an exemplary embodiment of the present invention.

### DEFINITIONS

For the purposes of the present disclosure, the term “on” may mean directly on top of a layer; alternatively “on” may mean “over,” with one or more intervening layers. In addition, for the purposes of the present disclosure, the term “optical device” means active optical device, or optoelectronic device; whereas the term passive optical element takes its customary meaning.

### DETAILED DESCRIPTION

In the following detailed description, for purposes of explanation and not limitation, exemplary embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention.

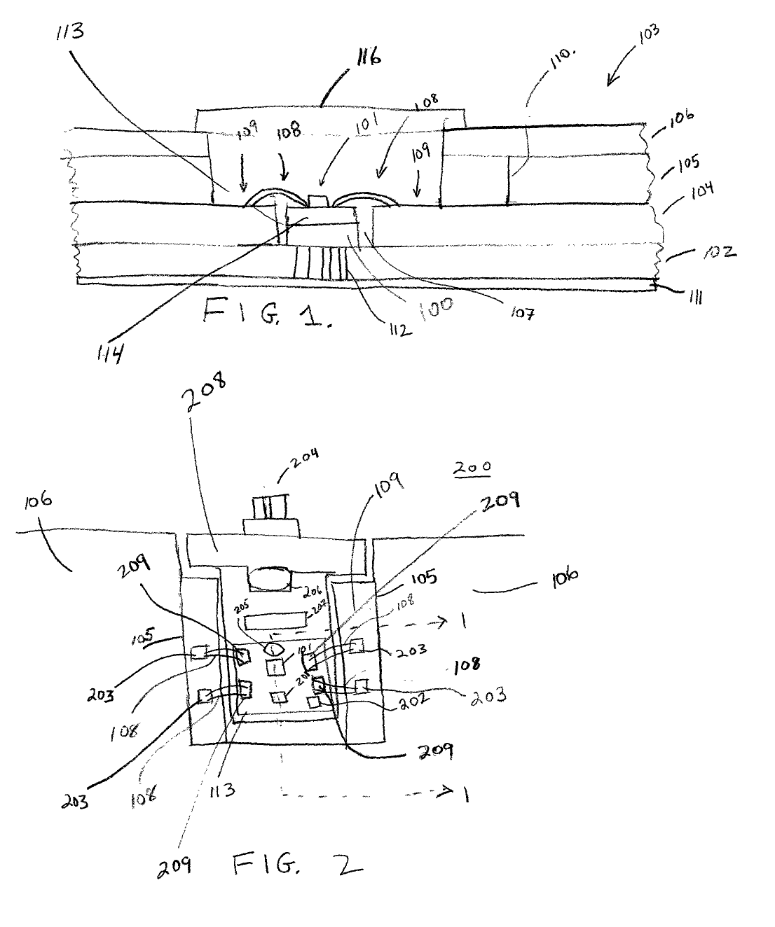

Turning to FIG. 1, a cross-sectional view along line 1-1 of FIG. 2 is shown. An assembly 113 illustratively includes an optical device 101 disposed on a layer 114, which is disposed on a base 100. The assembly 113 may include electrical devices (not shown in FIG. 1), as well. The assembly 113 is disposed on a substrate 102. This substrate 102 may be one layer of a multi-layer circuit board 103, which may be a multi-layer circuit board or a multi-layer circuit board 103 of ceramic composition. The multi-layer circuit board 103 illustratively includes layers 104, 105 and 106. If the substrate is a layer of a multi-layer circuit board, an electrically conductive layer 111, commonly referred to as cladding layer, may be disposed on the substrate 102 as shown. The electrically conductive layer 111 is relatively thick and is illustratively a metal such as copper (Cu). Vias 112 are filled with electrically conductive material, and may be used to provide an improved thermal path from substrate 102 to electrically conductive layer 111 in an exemplary embodiment of the present invention. Moreover, the structure of the exemplary embodiment of FIG. 1 may include a lid 116.

As shown in FIG. 1, the assembly 113 is illustratively disposed in a cavity 107, 10 which is formed in the multi-layer circuit board 103. The cavity 107 may be at one level of the multi-layer circuit board 103, or the cavity 107 may be formed in multiple layers (i.e. at multiple levels) of the multi-layer circuit board 103. Electrical connections between the transmission lines of the multi-layer circuit board 103 and optical and electrical devices of assembly 113 are facilitated in the illustrative embodiment of the present invention by the interconnection ledge 109. To this end, wire or ribbon bonds 108 are illustratively used to electrically connect various devices of the assembly 113 to the interconnection ledge 109, which has transmission lines terminating thereon. Thereby the interconnection ledge 109 allows for a substantially direct electrical connection to transmission lines of the multi-layer circuit board 103. The interconnection ledge 109 may be at one level of the multi-layer circuit board 103, and further connection to another layer of the multi-layer circuit board 103 may be effected by the use of vias 110.

By virtue of the interconnection ledge 109 of the illustrative embodiment of the present disclosure, the electrical distance between the assembly 113 (and thus, the optical device 101), and the transmission lines which carry electrical signals is substantially minimized when compared to conventional lead frame assemblies of discrete package optoelectronic devices as described above. This results in an improvement in performance as described in more detail below. Moreover, the interconnection ledge 109 fosters impedance matching between the optical device(s) of the assembly 113 and the transmission lines of the multi-layer printed circuit board. Again, further details of these features and advantages of the present invention are described more fully herein.

Turning to FIG. 2, a top view of optical to electrical interconnect structure 200 including optical assembly 208 is shown. The assembly 113 has an optical device 101 disposed thereon. In the illustrative embodiment of FIG. 2, this optical device 101 is an emitter, such as a laser or laser diode. A rear-facet monitor 201 may be disposed on the assembly 113 and provides the requisite monitoring of the emitter 101, as is well known to one of ordinary skill in the art. A thermistor 202 is also shown on the laser assembly. Of course, further electrical devices (active and passive), optical devices and passive optical devices may be disposed on assembly 113, as needed. The wire or ribbon bonds 108 are shown making electrical connections from bond pads 209 of the assembly 113 to bond pads 203 on the interconnection ledge 109. The optical receptacle 204 acts as the optical interconnect between an optical fiber (not shown) and the optical device 101. Passive optical elements shown at 205 and 206 are also shown in the illustrative embodiment of the present invention. Additionally, a optical free-space optical isolator 207 is shown. Filled vias (not shown) similar to 112 can be fabricated in layers 104 and 102 to improve thermal conductivity from impedance matching resistors or active components on interconnection ledge 109 to metal cladding layer 111. Finally, active electrical devices including a laser driver IC may also be mounted on interconnection ledge 109.

The free-space optical isolator 207 is useful in providing protection to the optical device 101 (e.g. the laser diode) from external optical reflections introduced with connection to the transmission path. The free-space optical isolator 207 is illustratively latched garnet type, offering single or double stage optical isolation in the 40-60 dB ranges, respectively. Free-space optical isolator 207 typically includes an anti-reflection (AR) coating for custom optical wavelength ranges (20-40 nm), between 1250-1610 nm for S, C and L band use. Passive optical element 206 may be a spherical lens, and may be used to focus the free space collimated laser beam into an optical fiber waveguide positioned in optical receptacle 204. Passive optical element 205 may be an aspherical lens, which transforms the diverging laser optical output into a collimated beam for introduction to the free-space optical isolator 207. Of course, these passive optical elements 205, 206 may be a variety of passive components for differing applications. Accordingly, passive elements also may be diffractive elements, (e.g. holographic optical elements (HOE)), rod lenses, or graded refractive index (GRIN) lenses, to name a few examples.

As discussed above, the invention of the present disclosure has certain advantages when compared to discrete optoelectronic packages such as the conventional resin-molded and ceramic packages described above. Conventional resin-molded packages are generally not appropriate for millimeter and microwave integrated circuit applications due to frequency limitations which result from the packaging and the relatively long lead length required to effect electrical connections. Conventional ceramic packages also have frequency limitations due to relatively long leads necessary to effect electrical connections. In contrast, multi-layer structures, (e.g. those used in conjunction with an exemplary embodiment of the present invention), may be used in millimeter, microwave, RF and other high-frequency applications. Multi-layer circuit board structures foster integration because of a reduction of the overall area of the circuit structure, which has clear benefits in many applications where the size considerations are important. Additionally, multi-layer circuit boards provide good performance at a relatively low cost. In the structure shown in FIG. 1, the substrate 102 is the first layer of multi-layer circuit board 103. The second layer 104, third layer 105 and fourth layer 106 complete the multi-layer circuit board 103 of the illustrative embodiment of FIG. 1.

In the exemplary embodiment of FIG. 1, the multi-layer circuit board 103 has signal transmission lines (not shown), disposed on the various dielectric layers 102, 104, 105 and 106 of the multi-layer circuit board 103. Of course, suitable ground planes (not shown) are also disposed in the multi-layer circuit board 103, completing the transmission line structures in the multi-layer circuit board 103. Illustratively, the dielectric used in the multi-layer circuit board 103 may be of a ceramic composition, FR4, Rogers 4350™ or benzocyclobutene (BCB). Finally, as is shown in FIG. 1, vias 110 may be used to provide interconnection between different levels of the multi-layer circuit board 103 as well as signal isolation. Further details of the use of various materials such as BCB for high-speed electrical applications, and vias for interconnection and isolation may be found in U.S. Pat. No. 5,883,422 to Anand, et al. and U.S. Pat. No. 6,133,805, to Jain, et al., respectively. The disclosures of these U.S. patents are specifically incorporated by reference herein.

As mentioned previously, according to the exemplary embodiment of FIGS. 1 and 2, the interconnection ledge 109 fosters the ability to reduce the distance (or length) of the electrical connection between the devices of the assembly 113 (such as optical device 101) and the transmission lines, which are subsequently connected to electrical devices (not shown). The electrical devices which are connected to the transmission lines may be part of the multi-layer circuit board 103 or ultimately connected thereto. In the exemplary embodiment of FIG. 1, the signal transmission lines are those of the multilayer circuit board 103. These transmission lines may terminate as stripline or microstripline transmission lines on the interconnection ledge 109, and are selectively connected to bond pads 203. Thereby, the interconnection ledge 109 provides a substantially direct connection between the optical (and electrical) devices of the assembly 113 and the transmission lines of multi-layer circuit board 103. To this end, the wire or ribbon bonds 108 electrically connect the bond pads 209 of assembly 113 to the bond pads 203 of the interconnection ledge 109; and the interconnection ledge 109 is connected to transmission lines of the multi-layer circuit board 103. The interconnection ledge 109 enables the length of the electrical connection (illustratively a wire or ribbon bond) to be significantly reduced, which results in a reduction of the undesired affects of parasitic elements such as parasitic inductance, compared to conventional interconnect structures described above.

For illustrative and not limitive purposes, the distance (or length) of the electrical connection between the bond pads 209 on layer 114 of assembly 113 and the bond pads 203 of the interconnection ledge 109 may be on the order of approximately 0.05 λₛ, (for example at an illustrative 10 GHz design frequency; or 1.5 mm given εᵣ˜1 for air), where λₛ is the wavelength of the signal traversing the electrical connection. Accordingly, the interconnection ledge 109 is effective at minimizing the relatively uncontrolled impedance length through the wire or ribbon bond 108 that bridges (illustratively, but not necessarily, through the air) the electrical distance from layer 114 to the interconnection ledge 109. The above referenced distance (or length) of the electrical connection is illustrative. Generally, in order to minimize reflections, and therefore, standing waves, it is useful to keep the distance (or length) of the electrical connection (e.g. of the wire or ribbon bonds 108) on the order of less than 0.25 λₛ.

By virtue of the present invention, the frequency performance, which is limited in conventional discrete package optoelectronic devices to on the order of 10 GHz or less, is significantly improved. To this end, the high-frequency transmission range of the invention of the present disclosure may be above approximately 10 GHz and up to approximately 50 GHz.

Moreover, as described above, impedance matching may be problematic in conventional discrete package optoelectronic devices using lead frames. The electrical distance (or length) of the impedance discontinuity between the transmission lines on interconnection ledge 109 and the assembly 113, is significantly reduced compared to conventional structures. According to an exemplary embodiment illustrated in FIG. 1, because the dielectric above the interconnection ledge 109 is illustratively air, a transmission line from the multi-layer board terminates as a microstrip transmission line (microstripline), where the width of the micro-stripline is readily determined from the relative permittivity, εᵣ, and height of layer 104. Moreover, a strip-line impedance matching technique can be used between layers 104 and 105 as a transmission line from interconnection ledge 109 enters the multi-layer circuit board 103. In addition, miniature microwave resistors may be placed or fabricated on interconnection ledge 109; or on the surface of assembly 113 to provide impedance matching from electrical and optical devices of assembly 113 to the transmission lines that terminate at interconnection ledge 109 and that are disposed in the multi-layer circuit board 103.

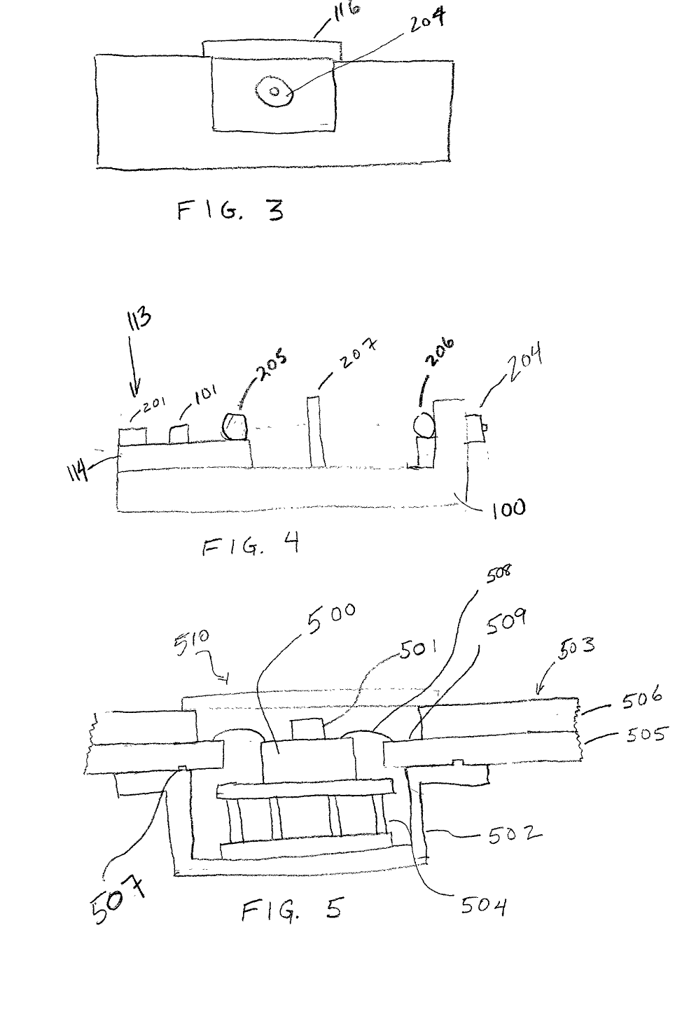

Turning to FIG. 4, a side/perspective view of the optical assembly 208 is shown. While the optical subassembly 208 is shown as being disposed in cavity 107 in the exemplary embodiment of FIGS. 1 and 2, it is of interest to note that this is intended to be illustrative, and not exhaustive of the ways in which the assembly 113 may be connected electrically to transmission lines. It is possible to directly attach the assembly 113 onto a multi-layer circuit board or other structure, without the use of a cavity (for example cavity 107). To this end, assembly 113 could be fabricated with vias (not shown) that are connected to bond pads on assembly 113. These pads could then be ribbon bonded to pads on the multi-layer circuit board 103. However, while possible, with this scheme the electrical distance (or length) is not optimally reduced. The exemplary embodiment of FIGS. 1 and 2, which includes cavity 107, reduces the electrical distance from the assembly 113 to desired circuit board connections (and thereby transmission lines) of the multi-layer circuit board 103 by having the top surface of assembly 113 approximately on the same plane as the top surface of the interconnection ledge 109. As discussed briefly above, the optical receptacle 204 is intended to receive an optical waveguide, illustratively an optical fiber. Of course, this is merely illustrative, and the invention of the present disclosure may be adapted for use with other types of optical waveguides such as planar optical waveguides. In the case of coupling to an optical fiber, the receptacle 204 may consist of a length of 1.25 mm or 2.5 mm diameter ceramic/zirconia ferrule with a single mode fiber (125 μm cladding diameter, 9 μm core diameter) mounted on axis. The base 100 of the assembly 113 is illustratively of metal composition, but could be of another material such as Kovar. The base 100 is readily bondable with layer 114, with suitable mechanical strength, and the base 100 has low thermal expansion to provide optical coupling stability between optical elements disposed thereon over a broad temperature range. Moreover, layer 114, on which electrical device 201, optical device 101 and passive optical element 205 are disposed, may be ceramic or of silicon composition (e.g. silicon optical bench or ceramic optical bench), with similar properties as base 100. To this end, layer 114 is illustratively a material of moderate-to-high electrical impedance, with a relatively low thermal impedance. This material must also have relatively good high frequency characteristics, including substantially low loss, and a substantially uniform and controlled dielectric constant. Often, monocrystalline silicon is used as the optical bench, as it is readily adaptable to etching for precise location of optical devices, and passive optical elements, such as lens 205, and alignment fiducials (not shown).

While the illustrative embodiment shown in FIG. 4 is drawn primarily to a transmitter, the invention of the present disclosure may be applied to a receiver, or to a transponder. To this end, in the embodiment of a receiver, layer 114 could be used to support a detector (not shown), such as a PIN detector or avalanche photodiode (APD), and any necessary components to support its function. For example, the detector could be connected to an amplifier section such as a transimpedance amplifier (not shown), also disposed on layer 114. In the embodiment of a transponder, a transmitter, such as a laser and necessary electronics/optical devices could be co-located with a receiver section on layer 114. To prevent cross-talk between the transmit and receive sections, suitable electrical isolation (not shown) may be used. Moreover, the transmit and receive sections may be on separate layers (not shown).

Turning to FIG. 5, another exemplary embodiment of the present invention is shown. The assembly 500 is substantially the same as assembly 113 described above, having an optical device 501 disposed thereover. The optical device 501 is electrically connected to the multi-layer circuit board 503 illustratively by wire or ribbon bonds 508. The multi-layer circuit board 503 illustratively includes layers 505 and 506. The structure shown in FIG. 5 includes a lid 510, and electrical connections are illustratively made by wire or ribbon bonds 508 to interconnection ledge 509. While the illustrative embodiment shown in FIG. 5 is substantially the same as that shown in FIGS. 1-4, the embodiment of FIG. 5 incorporates a cooling element 504, illustratively a thermoelectric cooler (TEC). As such, the advantages of reduced electrical distance (or length) of the interconnection and good impedance matching of the above described illustrative embodiments are attendant to the illustrative embodiment of FIG. 5, and are not repeated in the interest of brevity. The incorporation of the cooling element 504 is useful in applications where the operating temperature of active devices such as optical device 501 should be maintained at a substantially constant temperature. While the use of the cooling element is useful in applications where the optical device 501 is a laser or a laser diode, there are other instances where the cooling device 504 may be incorporated.

The cooling device 504 is illustratively disposed in a package case 502 which is aligned to the multi-layer circuit board 503 by alignment fiducials 507. The package case 502 is illustratively a material that affords relatively low thermal expansion properties and mechanical strength. Exemplary materials include metals, alloys and Kovar. By virtue of the illustrative embodiment shown in FIG. 5, the operating temperature of the optical device 501 may be maintained at a temperature range of 15-35° C., with the typical stability of <±0.1° C., depending on the feedback circuit design. The operating temperature range is determined by the temperature range of the package case 502 and the cooling capacity of the cooling device 504. As stated, cooling device 504 is a TEC, which typically offers an operating range of approximately 65° C. Therefore, the maximum case temperature would be illustratively +80° C. Finally, it is of interest to note that while the assembly 500 of illustrative embodiment of FIG. 5 is shown in a cavity of a multi-layer circuit board 503, this is not essential. As such, the assembly 500 and the cooling element may be disposed on the top of a transmission line structure such as a multi-layer circuit board, or other structure.

The invention having been described in detail it will be readily apparent to one having ordinary skill in the art that the invention may be varied in a variety of ways. Such variations are not to be regarded as a departure from the scope of the invention. All such modifications as would be obvious to one of ordinary skill in the art, having had the benefit of the present disclosure, are intended to be included within the scope of the appended claims.

We claim:

1. A structure for coupling an optical device to an electrical device, comprising:
a substrate over which an assembly is disposed;
at least one transmission line; and
an interconnection ledge which connects the optical device to said at least one transmission line.

2. A structure as recited in claim 1, wherein said substrate is in a cavity, and said assembly is disposed in said cavity.

3. A structure as recited in claim 1, wherein said at least one transmission line is disposed in a multi-layer circuit board.

4. A structure as recited in claim 3, wherein said interconnection ledge is at one level of said multi-layer circuit board.

5. A structure as recited in claim 3, wherein said cavity is at one level of said multi-layer circuit board.

6. A structure as recited in claim 3, wherein said substrate is one layer of said multi-layer circuit board.

7. A structure as recited in claim 3, wherein at least one via electrically connects said interconnection ledge to said at least one transmission line.

8. A structure as recited in claim 1, wherein said assembly further includes the optical device, another optical device and another electrical device.

9. A structure as recited in claim 1, wherein said interconnection ledge is impedance matched to said optical device.

10. A structure as recited in claim 1, wherein at least one wirebond connects said optical device to said interconnection ledge.

11. A structure as recited in claim 1, wherein the assembly further includes a layer and at least the optical device is disposed over a layer, and said layer and said interconnection ledge each include at least one bond pad.

12. A structure as recited in claim 11, wherein said at least one bond pad of said layer and said at least one bond pad of said interconnection ledge are electrically connected, and said electrical connection has a length of less than one-fourth of a wavelength of a signal traversing said electrical connection.

13. A structure as recited in claim 11, wherein said at least one bond pad of said layer and said at least one bond pad of said interconnection ledge are electrically connected and said electrical connection has a length in the range of approximately 0.05 λₛ to approximately less than 0.25 λₛ, where λₛ is the wavelength of a signal traversing said electrical connection.

14. A structure as recited in claim 11, wherein said layer and said interconnection ledge each have top surfaces, and said top surfaces are substantially co-planar.

15. A structure for connecting an optical device to an electrical device, comprising:
an assembly;
at least one transmission line; and
at least one electrical connection which connects said assembly to said at least one transmission line, said at least one electrical connection having a length of less than one-fourth of a wavelength of a signal traversing said at least one electrical connection.

16. A structure as recited in claim 1, wherein said assembly is disposed in a cavity.

17. A structure as recited in claim 1, wherein said at least one transmission line is disposed in a multi-layer circuit board.

18. A structure as recited in claim 15, wherein said assembly includes a layer, which includes at least one bond pad, and at least the optical device is disposed over said layer.

19. A structure as recited in claim 18, wherein said at least one transmission line is connected to an interconnection ledge which includes at least one bond pad, and said electrical connection is between said bond pad of said layer and said bond pad of said interconnection ledge.

20. A structure as recited in claim 19, wherein said interconnection ledge has a top surface, said layer has a top surface, and said top surface of said interconnection ledge and said top surface of said layer are substantially co-planar.

21. A structure as recited in claim 15, wherein said length is in the range of approximately 0.5 λₛ to approximately less than 0.25 λₛ, where λₛ is a wavelength of a signal traversing said electrical connection.

22. A structure as recited in claim 15, wherein at least the optical device is disposed over said layer.

23. A structure as recited in claim 15, wherein said assembly includes another electrical device.

24. A structure as recited in claim 15, wherein said assembly includes at least one passive optical element is disposed over said layer.
